(19) United States
(12) Patent Application Publication
(10) Pub. No.: US 2013/0207281 A1
(43) Pub. Date: Aug. 15, 2013

(54) MICROELECTRONIC SUBSTRATE COMPRISING A LAYER OF BURIED ORGANIC MATERIAL

(71) Applicant: Commissariat A L'Energie Atomique Et Aux Ene Alt, (US)

(72) Inventors: Xavier BAILLIN, Crolles (FR); Jean-Louis Pornin, Crolles (FR)

(73) Assignee: Commissariat A L'Energie Atomique Et Aux Ene Alt, Paris (FR)

(21) Appl. No.: 13/764,244

(22) Filed: Feb. 11, 2013

(30) Foreign Application Priority Data
Feb. 15, 2012 (FR) 12 51397

(51) Int. Cl. B81C 1/00; B81B 3/00

(52) U.S. Cl. CPC B81C 1/00134; B81B 3/0018
USPC 257/787; 438/127

(57) ABSTRACT

Microelectronic substrate comprising at least:
a support layer,
a top layer comprising at least one semiconductor,
a layer comprising at least one organic material able to be etched selectively with respect to the semiconductor of the top layer by using a dry etching, and disposed between the support layer and the top layer,
and also comprising one or more portions of dielectric material the hardness of which is greater than that of the organic material, disposed in the layer of organic material, and the thickness of which is substantially equal to that of the layer of organic material.

### TECHNICAL FIELD

The present invention concerns a microelectronic substrate and a method of producing such a substrate, comprising at least one layer of buried organic material able to serve as a sacrificial layer for the substrate. Such a microelectronic substrate is advantageously used for producing microelectronic devices, for example of the MEMS (microelectromechanical system) and/or NEMS (nanoelectromechanical system) type intended to be encapsulated. The invention also concerns such a microelectronic device and a method for producing such a microelectronic device.

### PRIOR ART

A microelectronic device of the MEMS and/or NEMS type, comprising for example a resonant structure, is produced from a substrate of the SOI (Silicon On Insulator) type. The top layer of the SOI substrate composed of monocrystalline silicon is first all etched using an anisotropic deep reactive ion etching (DRIE) with stoppage on the buried oxide layer (called BOX, standing for “Buried Oxide”) of the SOI substrate, in order to form the various elements, fixed and movable, of the microelectronic device. Part of the buried oxide layer is then etched using for example hydrofluoric (HF) acid in vapor form in order to release the movable elements of the microelectronic device with respect to the rest of the buried oxide layer.

An encapsulation of the device is then carried out by transferring and hermetically fixing a cap, corresponding for example to a second substrate composed of semiconductor or glass, on the SOI substrate (packaging of the “Wafer to Wafer” or W2W type). To produce a controlled atmosphere in the cavity (for example a vacuum or the presence of a particular gas, pressure, etc.) necessary to the correct functioning of the device, a getter material in a thin layer is deposited in the cavity prior to the closure thereof, for example against the cap or on the top face of the substrate.

Such a method of producing and encapsulating the microelectronic device has several drawbacks. First of all, wet etching of the buried oxide layer with hydrofluoric acid poses a problem of compatibility vis-à-vis the getter material, generally composed of one or more metals, because the metals do not resist this acid. The getter material must therefore be added in the cavity after this HF etching.

This etching of the buried oxide also poses problems relating to the particulate pollution caused by this etching, since particles generated by this etching may be deposited on the microelectronic device. Thus, when the device comprises for example interdigitated combs, the spacing between those of the movable part of the device and those of the fixed part of the device being of the order of a few microns in the case of capacitive detection, these particles may interfere with the functioning of the microelectronic device by being deposited in this space.

The use of an SOI substrate also represents a high cost. In addition, a cap produced by transferring a second substrate onto the SOI substrate is bulky, in particular because of the sealing bead used that guarantees both mechanical strength and airtightness of the packaging produced, and which generally has a width of around 100 μm.

Finally, a method of encapsulation by substrate transfer requires a large number of precautions to be complied with in order to obtain a high vacuum in the cavity or a rigorously controlled atmosphere. This is because this encapsulation is carried out in a sealing chamber where the minimum vacuum level that may be obtained is around a few 10⁻⁶ mbar. With such a pressure, there exists a risk of contaminating the getter during the sealing cycle and therefore reducing its pumping capacity.

For other devices such as non-cooled infrared detectors of the bolometer type, producing these devices on a semiconductor substrate of the bulk type is known, and then effecting an encapsulation of the TFP (“Thin Film Packaging”) type of these devices.

The microbolometers are produced or assembled on the top face of the semiconductor substrate, using sacrificial layers produced on the top face of the substrate.

The devices are then covered with a layer of sacrificial material, for example composed of resin, shaped according to the geometry of the required cavity.

This sacrificial material is then covered with one or more thin encapsulation layers intended to form the cap. The sacrificial material is then etched via vents produced through the cap. Finally, the vents are plugged by a plugging material so as to make the cavity hermetic, and optionally under controlled atmosphere if this is necessary to the correct functioning of the devices.

As in the case of packaging by cap transfer, a getter in a thin film may be deposited on the substrate prior to the implementation of the steps of encapsulation of the microelectronic device. The getter material may also be deposited on the sacrificial material, prior to the deposition of the encapsulation layer or layers, forming together the cap (the getter material then forming the internal wall of the cap). The document FR 2 822 541 describes the implementation of such a method.

This method has the advantage of not having recourse to an SOI substrate, which obviously avoids the problems related to the cost of the substrate itself as well as to those relating to the etching of the buried oxide layer.

The overall size of the assembly obtained is also reduced compared with an encapsulation by substrate transfer. Finally, in the case of plugging of the vents with a metal, it is possible to effect the deposition of this metal by evaporation under a vacuum of around 10⁻⁷ mbar, which makes it possible to obtain a higher vacuum level in the cavity.

The plugging material used may be a getter material.

On the other hand, such a method is not suited to the production of devices of the MEMS and/or NEMS type, in particular when they comprise movable parts, which require to be produced in an SOI substrate. In the case of an MEMS/NEMS device produced in advance in a SOI substrate and encapsulated by TFP, it is necessary to release the structure of the device by HF wet etching, and then to deposit a sacrificial resin on the structure thus released. Apart from the addition of technological steps generated in this case, there also exists a risk of affecting the movable part of the device (impacts, particles, bonding on the fixed part) with little guarantee with regard to the uniformity of the thickness of the sacrificial resin deposited on all the structures because of the topology.

### DISCLOSURE OF THE INVENTION

Thus there is a need to propose a microelectronic substrate from which it is possible to produce and encapsulate microelectronic devices without the drawbacks of the prior art previously described.

For this purpose, one embodiment proposes a microelectronic substrate comprising at least:
a support layer,
a top layer comprising, or composed of, at least one semiconductor,
a layer comprising, or composed of, at least one organic material able to be etched selectively with respect to the semiconductor of the top layer by using a dry etching, and disposed between the support layer and the top layer.

Another embodiment also concerns a microelectronic substrate comprising at least:
a support layer,
a top layer comprising, or composed of, at least one semiconductor,
a layer comprising, or composed of, at least one organic material able to be etched selectively with respect to the semiconductor of the top layer by using a dry etching, and disposed between the support layer and the top layer,

and also comprising one or more portions of dielectric material the hardness of which is greater than that of the organic material, disposed in the layer of organic material, and the thickness of which is substantially equal to that of the layer of organic material.

The layer of organic material may correspond to a layer of resin comprising, or based on, at least one polymer material. The organic material is advantageously a dielectric material. Its thickness is for example between a few microns and a few tens of microns (for example between approximate 1 μm and 100 μm). The material of this layer is degradable by dry etching (for example etching by a gas or plasma, for example of the oxidizing type) and may be eliminated selectively with respect to the semiconductor of the top layer. The organic material may also have adhesion properties and optionally be photosensitive.

Such a substrate may therefore be used for producing microelectronic devices, advantageously devices of the MEMS and/or NEMS type produced collectively, by means of the layer of organic material serving as a buried or embedded sacrificial layer.

Compared with a solid substrate of the bulk type, microelectronic devices may be produced in such a substrate without using a step of surface assembly of the substrate.

The elements of the microelectronic devices may be produced directly in the substrate and formed by one or more parts of the top semiconductor layer.

The microelectronic substrate proposed may therefore be in the form of a stack of layers, each in the form of a disc the diameter of which is for example between approximately 100 mm and 300 mm.

The organic material of the layer may therefore be etched by a dry etching which, contrary to wet etching, does not cause particulate pollution, for example using oxidizing plasma.

In addition, such a substrate is compatible with an encapsulation of the TFP type or by cap transfer (for example the transfer of a substrate) of microelectronic devices produced in this substrate.

The element called the “support layer” may be a single layer or several stacked layers.

The substrate may be produced at less cost if the material of the support layer is inexpensive, such as for example metal, glass or polycrystalline silicon (unlike an SOI substrate). In general terms, any layer of material with a thickness of between a few hundreds of microns and a few mm, having surface evenness (or TTV, standing for “Total Thickness Variation”) less than approximately 10 μm and the deflection of which is less than approximately 100 μm, may serve as a support layer.

The organic material may be a resin, for example photosensitive.

This resin advantageously has negative polarity, such as for example polyimide or BCB (benzocyclobutene). For this type of resin, the layer of organic material then has adhesion vis-à-vis the support layer and the top layer, thus facilitating the production of the substrate. In general terms, any polymer that is selectively degradable by dry etching vis-à-vis the top layer may be used as an organic material in this substrate.

The polymer may be suitable for bonding the support layer and the top layer.

The electronic substrate may also comprise at least one layer of getter material disposed between the support layer and the layer of organic material. Thus, when a microelectronic device is produced in the substrate, the etching of the organic material effected to release the microelectronic device (elements of which, such as fixed or movable parts, are formed by parts of the top semiconductor layer) reveals part of the layer of getter material situated under the etched organic material and which is intended to be encapsulated in the cavity in which the microelectronic device is encapsulated, this material helping to effect a gaseous adsorption and/or absorption in the encapsulation cavity of the device.

The substrate may also comprise at least two other layers, for example dielectric, secured directly against each other and disposed between the layer of organic material and the top layer. These two layers, which are secured to each other by direct bonding (without adhesion material disposed between these two layers), may comprise, or be composed of, semiconductor oxide and/or semiconductor nitride. The cost of such a substrate is less than that of an SOI substrate. In addition, the sacrificial organic layer, through its low mechanical rigidity, limits the residual stresses due to the assembly between the support layer and the top layer when direct bonding between these two layers is carried out, this bonding being carried out at a temperature lower than the degradation temperature of the organic material.

The substrate may also comprise one or more portions of dielectric material the hardness of which is greater than that of the organic material, disposed in the layer of organic material, and the thickness of which may be substantially equal to that of the layer of organic material. These portions of dielectric material may advantageously comprise, or be composed of, semiconductor oxide and/or nitride. Such portions of material form spacers, or studs, or stops, rigid vis-à-vis the two layers disposed against the layer of organic material on each side thereof. Thus, when the substrate is produced, the layer of organic material is not crushed uniformly by these layers since the portions of rigid material provide substantially constant spacing between these layers that corresponds to the thickness of the layer of organic material, these layers therefore being positioned parallel to each other.

The substrate may also comprise one or more holes produced through the layer of organic material.

The substrate may also comprise at least one portion of dielectric material (advantageously comprising, or composed of, semiconductor oxide and/or semiconductor nitride) disposed in the layer of organic material, able to form a closed contour around at least one region of the layer of organic material. At least one of the portions of dielectric material disposed in the layer of organic material may form a closed contour around at least one region of the layer of organic material. This portion of dielectric material may therefore delimit a region of organic material which, when a microelectronic device is produced in the substrate at this region, is intended to be etched when the microelectronic device is released. The fact that the portion of dielectric material forms a closed contour of this region makes it possible to clearly delimit the region of organic material that will be etched when the microelectronic device is released.

The thickness of this portion of dielectric material may be substantially equal to that of the layer of organic material.

Another embodiment also concerns a microelectronic device comprising a microelectronic substrate as defined above, comprising at least one portion of the top layer suspended above the support layer. This suspended portion may be obtained by implementing a dry etching of part of the layer of organic material. Since the organic material may be etched selectively with respect to the semiconductor of the top layer of the substrate, it is therefore possible to release the parts, for example movable parts, of the device formed by one or more portions of the top layer.

Another embodiment also concerns a method of producing a microelectronic substrate, comprising at least the steps of:
producing a layer comprising, or composed of, at least one organic material on a support layer;
producing a top layer comprising, or composed of, at least one semiconductor on the layer of organic material, the organic material being able to be etched selectively with respect to the semiconductor of the top layer using a dry etching.

Another embodiment concerns a method of producing a microelectronic substrate, comprising at least the steps of:
producing a layer comprising, or composed of, at least one organic material on a support layer;
producing a top layer comprising, or composed of, at least one semiconductor on the layer of organic material, the organic material being able to be etched selectively with respect to the semiconductor of the top layer using a dry etching;

and also comprising, before the production of the layer of organic material, a step of producing one or more portions of a dielectric material the hardness of which is greater than that of the organic material, on the support layer, the thickness of which is substantially equal to that of the layer of organic material, the layer of organic material then being produced on the support layer, around said portion or portions.

The method of producing the microelectronic substrate may also comprise, before the layer of organic material is produced, a step of producing at least one layer of getter material on the support layer, the layer of organic material being produced on the layer of getter material. The portion or portions of dielectric material may be produced on the layer of getter material.

The production of the top layer on the layer of organic material may comprise at least one step of direct bonding between the other two layers, one being able to be disposed against the top layer and the other being able to be disposed against the layer of organic material. These direct bonding layers are advantageously composed of, or comprise, at least one dielectric material.

The method of producing the substrate may also comprise, before the production of the layer of organic material, a step of producing one or more portions of a dielectric material the hardness of which is greater than that of the organic material, on the support layer or, when the method comprises a step of producing at least one layer of getter material on the support layer, on the layer of getter material, the thickness of which may be substantially equal to that of the layer of organic material, the layer of organic material being able then to be produced on the support layer or on the layer of getter material, around said portion or portions.

The method of producing the substrate may also comprise, before the top layer is produced, a step of producing one or more holes through the layer of organic material. Thus, when the top layer is produced on the layer of organic material, which may involve a crushing of the layer of organic material, this hole or holes affords better control of this crushing and in particular of the deformation of the layer of organic material.

The method of producing the substrate may also comprise, before the layer of organic material is produced, a step of producing at least one portion of dielectric material (advantageously semiconductor oxide and/or semiconductor nitride) on the support layer or, when the method comprises a step of producing at least one layer of getter material on the support layer, on the layer of getter material, said portion being able to form a closed contour around at least one region of the layer of organic material then produced on the support layer or on the layer of getter material.

The method may also comprise the production of at least one of the portions of dielectric materials such that said portion forms a close contour around at least one region of the layer of organic material.

Another embodiment also concerns a method of producing at least one microelectronic device, comprising at least the steps of:
producing the microelectronic device in the top layer of a microelectronic substrate as previously defined;
elimination by dry etching of part of the layer of organic material disposed under the microelectronic device such that the microelectronic device comprises at least one portion of the top layer suspended above the support layer.

The method of producing the microelectronic device may also comprise, between the step of producing the microelectronic device and the step of eliminating part of the layer of organic material, at least the steps of:
producing, on the top layer of the microelectronic substrate, a portion of material able to be etched selectively with respect to the semiconductor material of the top layer and covering the microelectronic device;
depositing at least one encapsulation layer on the portion of material covering the microelectronic device;
etching the portion of material covering the microelectronic device through at least one opening produced through the encapsulation layer;

and also being able to comprise, after the step of elimination of part of the layer of organic material disposed under the microelectronic device, a step of hermetic closure of the opening or openings produced through the encapsulation layer.

The step of etching the portion of material covering the microelectronic device and the step of eliminating part of the layer of organic material may be a single dry etching step. It is therefore possible to release the microelectronic device and the cavity in which the microelectronic device is encapsulated in a single technological step.

In addition, the whole of the structure may be degassed in a single cycle before the plugging step, thus guaranteeing uniform degassing and ensuring plugging under controlled pressure conditions.

The method may also make it possible to encapsulate several components in the same atmosphere.

The method may also comprise, between the step of producing the microelectronic device and the step of eliminating part of the layer of organic material, a step of transferring and sealing a cap (for example made from silicon or glass) on the top layer, in which the elimination of part of the layer of organic material may be carried out through at least one opening formed through the cap and may also comprise a step of hermetic closure of the opening produced through the cap.

The sealing of the cap may be anodic sealing, metal sealing or direct sealing.

### BRIEF DESCRIPTION OF THE DRAWINGS

The present invention will be understood better from a reading of the description of example embodiments given purely by way of indication and in no way limitatively, with reference to the accompanying drawings, in which:

FIGS. 1 to 7 show views in profile section or from above of microelectronic substrates with a layer of buried organic material, according to several embodiments;

FIGS. 8A to 8F show the steps of a method of producing a microelectronic device in a microelectronic substrate with a layer of buried organic material, according to a particular embodiment;

FIG. 9 shows a microelectronic device produced from a microelectronic substrate with a layer of buried organic material, according to a particular embodiment.

Identical, similar or equivalent parts of the various figures described below bear the same numerical references so as to facilitate passing from one figure to another.

The various parts shown in the figures are not necessarily shown to a uniform scale, in order to make the figures more legible.

The various possibilities (variants and embodiments) must be understood as not being exclusive of one another and may be combined with one another.

### DETAILED DISCLOSURE OF PARTICULAR EMBODIMENTS

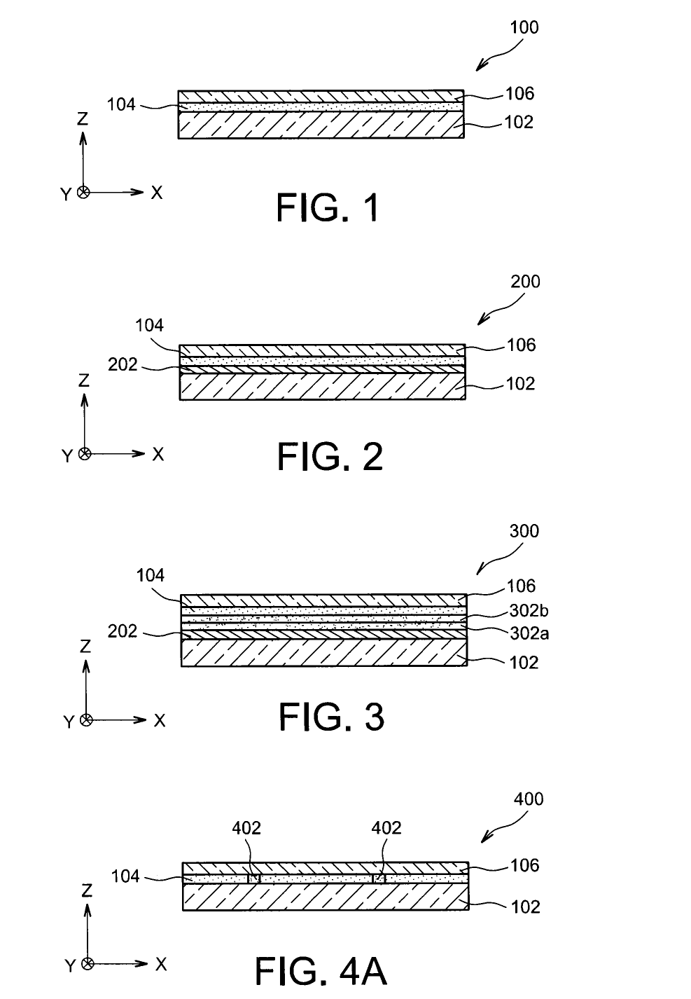

Reference is made first of all to FIG. 1, which shows a microelectronic substrate 100 with a layer of buried, or embedded, organic material, according to a first embodiment.

The substrate 100 comprises a support layer 102, the thickness of which is for example greater than or equal to approximately 100 μm, serving as a mechanical support for the other elements of the substrate 100. This support layer 102 comprises, or is composed of, a semiconductor such as monocrystalline or polycrystalline silicon, or any other material for producing the support layer 102 in the form of a flat circular substrate the diameter of which is for example between approximately 100 mm and 300 mm. The support layer 102 may also comprise, or be composed of, glass or any other material sufficiently rigid to prevent or limit the curvature of the semiconductor substrate 100 (metal, polymer, etc.).

The support layer 102 is covered with a layer 104 comprising, or composed of, at least one organic material, for example a resin or a material of the polyimide type. According to its nature, the organic material may have adhesive properties contributing to the mechanical connection between the support layer 102 and a top layer 106 comprising, or composed of, at least one semiconductor and covering the organic layer 104.

Thus the organic layer 104 may comprise, or be composed of, one or more materials generally used for effecting sealing between two substrates, such as negative-polarity photosensitive resins that have adhesive properties, for example of the BCB type. In general terms, the organic layer 104 may comprise, or be composed of, any organic material withstanding a temperature of between 250° C. and 400° C. and able to be destroyed by dry etching, for example using one or more gases such as a fluorinated or chlorinated gas of the SF₆ and/or CF₄ type, and/or a plasma, for example an oxidizing plasma. Such a material may withstand the technological steps implemented when a microelectronic device is produced in the top layer 106, while being compatible with subsequent elimination thereof by etching other than HF etching, for example by an oxidizing plasma. The layer 104 has for example a thickness of between approximately 1 μm and 100 μm. The material of the layer 104 is advantageously, dielectric.

This layer 104 will subsequently serve as a sacrificial layer when microelectronic devices are produced in the substrate 100.

Finally, the substrate 100 comprises the top layer 106 comprising, or composed of, semiconductor such as for example monocrystalline silicon, disposed on the organic layer 104 and the thickness of which is between a few microns and a few tens of microns, for example between approximately 1 μm and 100 μm. The material of the top layer 106 is chosen in order then to be able to serve for producing microelectronic devices, for example of the MEMS and/or NEMS type, in this top layer 106.

The substrate 100 is produced by first of all depositing the organic layer 104 on the support layer 102, for example by implementing a spin coating step. The top layer 106 is then connected to the organic layer 104, for example by thermocompression.

This thermocompression may be carried out in a sealing chamber under primary vacuum and at a temperature of between approximately 200° C. and 300° C. so as to be able to crosslink the organic material of the layer 104. If the thickness of the top layer 106 is greater than the required final thickness, this thickness of the sacrificial layer 106 is reduced for example by implementing a mechanical machining by grinding. Whether or not the top layer 106 has undergone this machining step, the front face of the top layer 106 (the face opposite to the one in contact with the organic layer 104) may undergo chemical-mechanical polishing (CMP) reducing the surface topologies of this front face.

FIG. 2 shows a substrate 200 with a layer of buried organic material according to a second embodiment.

Compared with the substrate 100 previously described, the substrate 200 comprises a layer of getter material 202, for example comprising, or composed of, at least one metal, disposed between the support layer 102 and the organic layer 104. Thus, when part of the organic layer 104 is eliminated during the release of a microelectronic device produced in the top layer 106, the getter material part of the layer 202 situated under the etched part of the organic layer 104 is then once again exposed to the atmosphere of the cavity in which the microelectronic device is encapsulated, helping to control the atmosphere in the cavity when the getter material is subsequently thermally activated.

The substrate 200 is obtained by implementing the same steps as those previously described for producing the substrate 100, except that, prior to the deposition of the organic layer 104, the layer of getter material 202 is first deposited by PVD (physical vapor deposition), on the support layer 102, the organic layer 104 then being deposited on the layer of getter material 202.

FIG. 3 shows a substrate 300 with a layer of buried organic material, according to a third embodiment.

Like the substrate 200 previously described, the substrate 300 comprises the support layer 102, the layer of getter material 202, the layer of organic material 104 and the top semiconductor layer 106. The substrate 300 also comprises, between the top layer 106 and the organic layer 104, two other layers 302a, 302b, here dielectric layers comprising, or composed of, silicon oxide, assembled against each other by direct bonding.

The two layers 302a, 302b are present in the substrate 300 because of the steps implemented for producing the substrate 300. A first part of the substrate 300 is first of all formed by producing the layer of getter material 202 and the organic layer 104 on the support layer 102 as previously described for the substrate 200. The layer 302a is then produced on the organic layer 104, for example by CVD (chemical vapor deposition). A second part of the substrate 300 is produced independently of the first part by forming the layer 302b on the top layer 106, for example by thermal oxidation of a face of the top semiconductor layer 106. The layers 302a, 302b are then polished by CMP. The two parts produced independently of each other are then assembled by effecting a direct bonding of the layers 302a, 302b against each other.

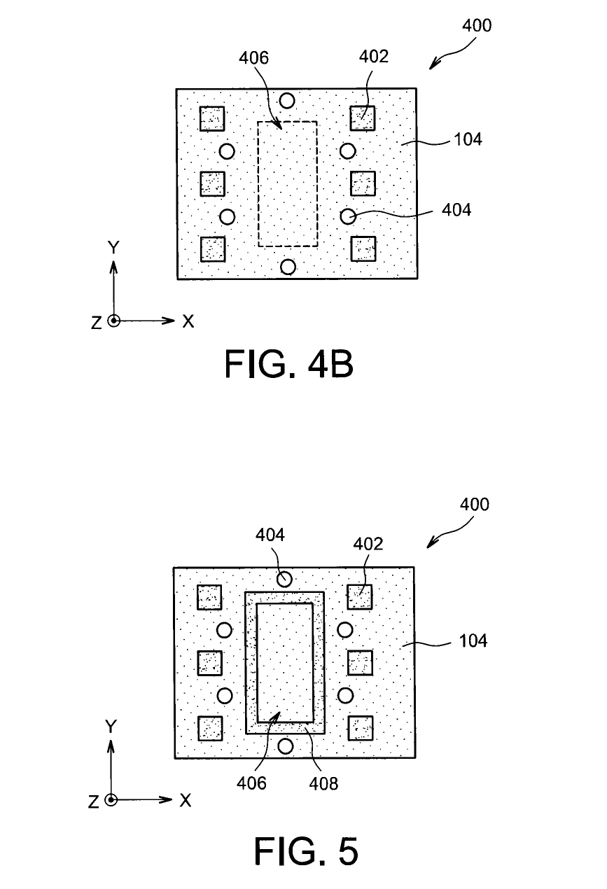

FIGS. 4A and 4B show respectively a view in profile section and a view in plan section of a substrate 400 with a layer of buried organic material according to a fourth embodiment.

Like the substrate 100 previously described, the substrate 400 comprises the support layer 102, the layer of buried organic material 104 and the top semiconductor layer 106. The substrate 400 also comprises portions 402 of dielectric material, here silicon oxide, interposed between the support layer 102 and the top layer 106, in the layer of organic material 104. These portions 402 form shims, or stops, for keeping the support layer 102 and the top layer 106 parallel to each other when the substrate 400 is produced. This is because, when the top layer 106 is assembled on the organic layer 104, for example by thermocompression, the top layer 106 crushes the organic layer 104, which may be deformed in an irregular fashion and cause a non-parallel placing of the top layer 106 with respect to the support layer 102. By forming the portions 402 in the organic layer 104 with a thickness equal to that of the organic layer 104, these portions 402 will form stops on which the top layer 106 will bear during assembly with the organic layer 104, thus facilitating the parallel positioning of the top layer 106 with respect to the support layer 102.

In this fourth embodiment, holes 404 are also produced through the organic layer 104 in order better to control the crushing of the organic layer 104 when the top layer 106 is assembled on the organic layer 104. The holes 404 and the portions 402 are produced around a region 406, delimited symbolically by broken lines in FIG. 4B, representing the portion of the organic layer 104 that is intended to be etched subsequently on the release of a microelectronic device produced in the top layer 106, above this region 406 (the holes 404 and the portions 402 are produced around this region 406).

The portions 402 are produced on the support layer 102 prior to the deposition of the organic layer 104, by depositing first of all a layer of dielectric material on the support layer 102 and then etching this layer according to the patterns of the portions 402. The organic material of the layer 104 is then deposited on the support layer 102. The organic material deposited on the portions 402 is removed before continuing the production of the substrate 400. The holes 404 are then produced by photolithography and etching through the organic material of the layer 104. The method is then completed in a similar manner to that previously described for the previous substrates (production of the top layer 106, CMP, etc.).

FIG. 5 shows a view in plan section of the substrate 400 with a buried organic sacrificial layer according to a variant of the fourth embodiment.

In this variant embodiment, the region 406 is delimited by a portion of dielectric material 408 forming a bead surrounding the organic material of this region 106.

The dielectric material of the portion 408 corresponds for example to the one forming the portions 402 (here SiO₂). In addition, like the portions 402, the portion 408 may extend through the entire thickness of the organic layer 104, between the support layer 102 and the top layer 106. The portion 408 clearly delimits the portion of organic material to be etched, which corresponds to the part of the organic layer 104 situated in the region delimited by the portion 408. Apart from this delimitation function, this portion 408 also improves the sealing of the cavity that will be obtained by etching the region 406 of the organic layer 104.

The portion of dielectric material 408 and the portions 402 may be produced by implementing common steps of deposition of dielectric material, photolithography and etching of this dielectric material.

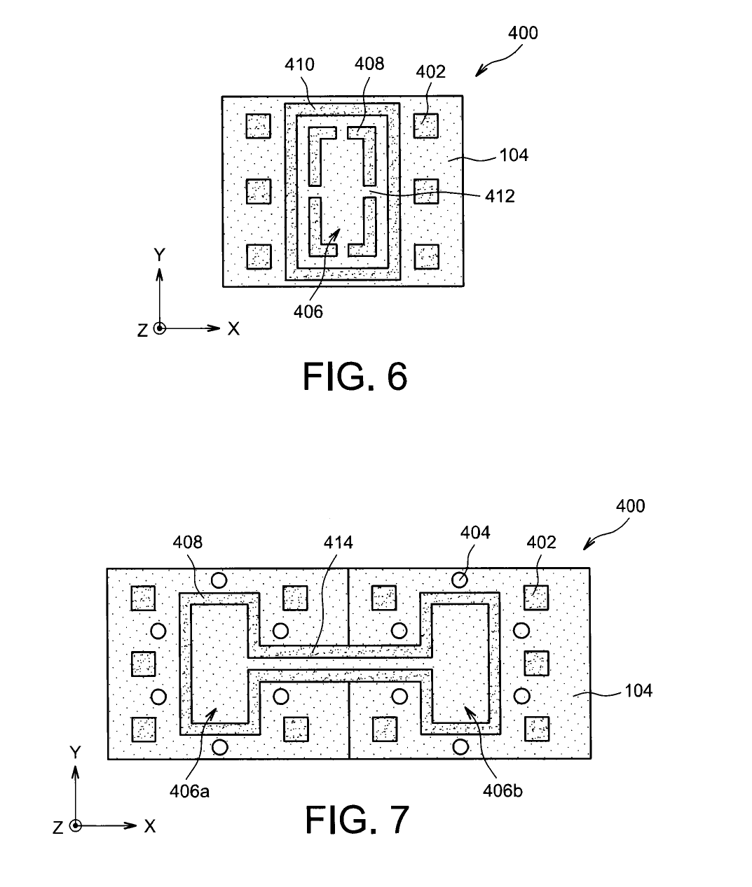

FIG. 6 shows a view in plan section of the substrate 400 with a buried organic sacrificial layer according to another variant of the fourth embodiment.

In this variant embodiment, the region 406 is delimited by the portion of dielectric material 408 as well as by a second portion 410 surrounding the first portion 408. In this variant, since the first portion 408 does not have a closed contour (the presence of channels 412 making the region 406 delimited by the first portion 408 communicate with the region delimited by the second portion 410, which for its part has a closed contour), the volume of the region of organic material that will be etched on release of the microelectronic device produced in the substrate 400 is increased, which reduces the pressure in the cavity formed for the same number of moles of gas trapped in this cavity.

Another variant embodiment of the substrate 400 is shown in FIG. 7.

In this variant, the portion 408 of dielectric material delimits two regions 406a, 406b intended to form two cavities in which two microelectronic devices will be encapsulated. The portion 408 also delimits a region 414 intended to form a channel making the two cavities formed at the regions 406a, 406b communicate. Thus the two microelectronic devices can be encapsulated hermetically in two different cavities in which the same atmosphere prevails.

The elements of the substrate 400 previously described in relation to FIGS. 4 to 7 (dielectric portions 402, 408, 410, holes 404) can be produced in the previously described substrates.

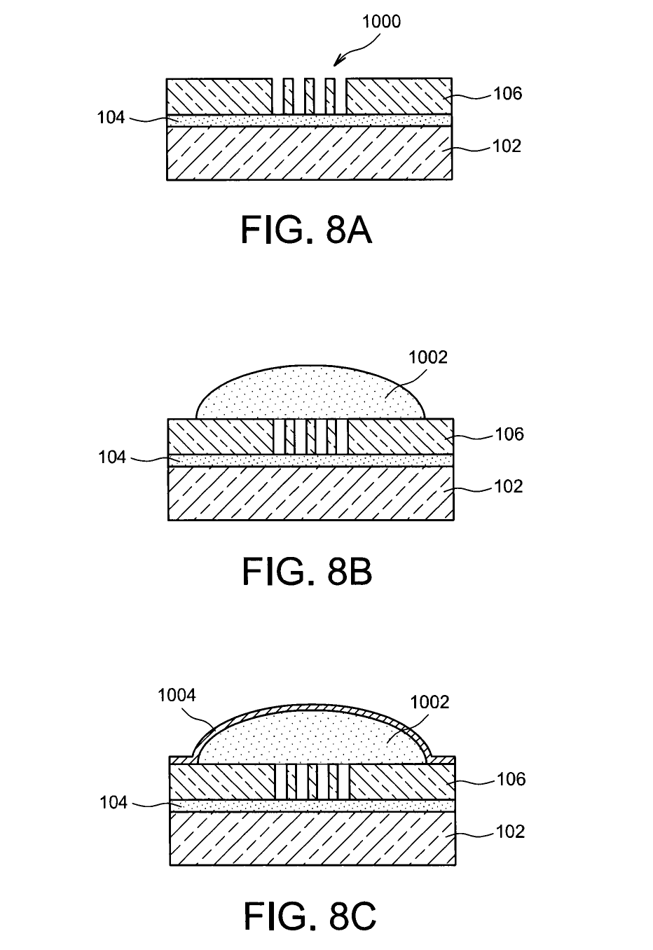

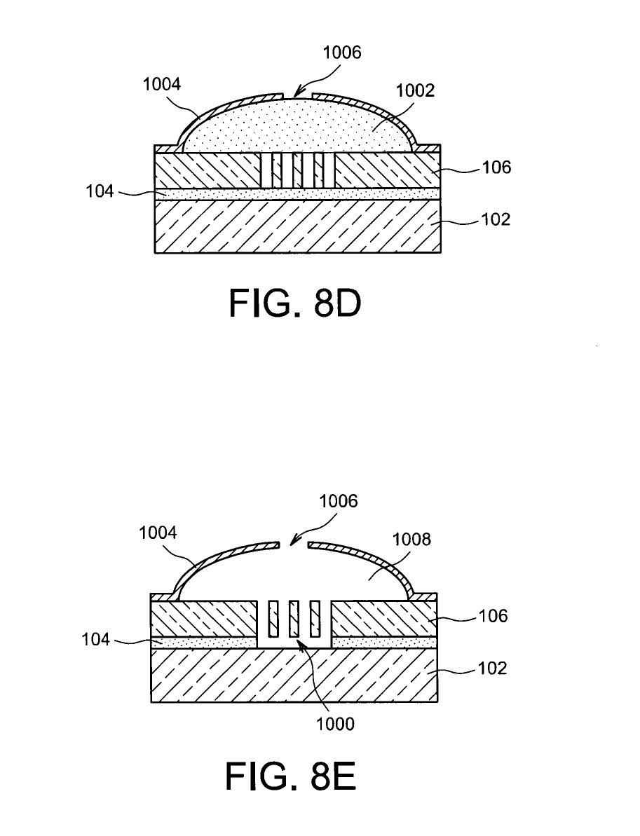

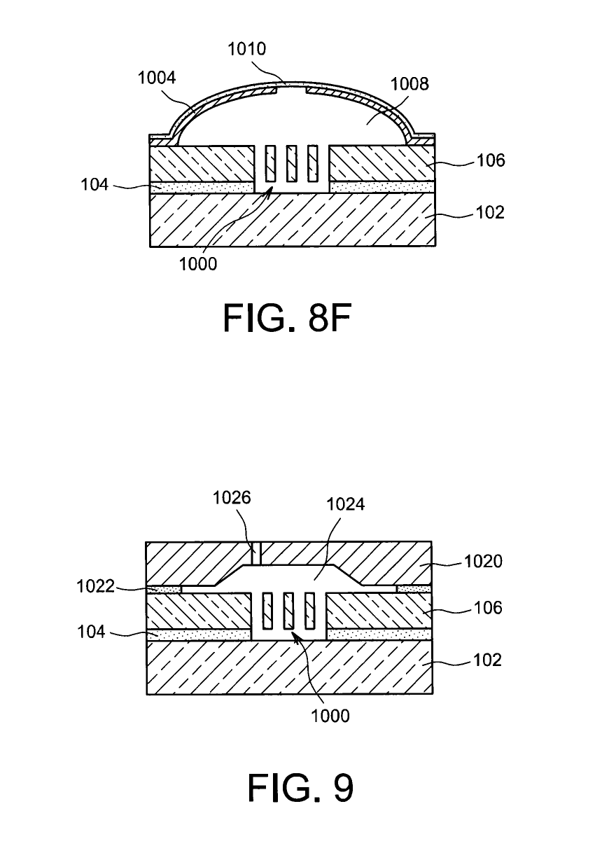

Reference is now made to FIGS. 8A to 8F, which show the steps of a method of producing a microelectronic device 1000 from a substrate with a sacrificial layer of buried organic material, corresponding here to the substrate 100 previously described.

As shown in FIG. 8A, the various parts of the device 1000 are produced in the top layer 106, for example via photolithography and etching steps (with stoppage on the buried organic layer 104).

A portion of sacrificial material 1002 is then produced on the device 1000, the form and dimensions of which correspond to the cavity in which the device 1000 is intended to be encapsulated. The portion of sacrificial material 1002 is for example produced by depositing a layer of this sacrificial material on the top layer 106 and then effecting a shaping by photolithography and etching of this layer of sacrificial material, and optionally by heat treatment for causing the sacrificial material to flow with a view to giving it a more rounded shape (FIG. 8B). Advantageously, the portion 1002 comprises, or is composed of, an organic material similar to that of the layer 104.

As shown in FIG. 8C, an encapsulation layer 1004 is then deposited on the portion of sacrificial material 1002. This encapsulation layer may comprise, or be composed of, semiconductor oxide and/or nitride (for example SiO₂ and/or SiN) and have a thickness of around a few microns.

This encapsulation layer 1004 is intended to form the cap of the cavity in which the device 1000 is intended to be encapsulated. In a variant, several encapsulation layers can be deposited and superimposed on the portion of sacrificial material 1002. It is for example possible to deposit first of all a layer of getter material (for example titanium or zirconium) covering the portion of sacrificial material 1002. One or more other encapsulation layers are then deposited on the layer of getter material. In this case a cap is formed, integrating a getter material at its internal face.

As shown in FIG. 8D, an opening 1006 or vent is then made, through the encapsulation layer or layers 1004. It is possible to produce several openings through the encapsulation layer 1004, in particular at the periphery of the device 1000. The diameter of the opening 1006 is between approximately 1 μm and a few microns.

The etching of the portion of sacrificial material 1002 is then carried out through the opening or openings 1006 previously made in the encapsulation layer or layers 1004 (FIG. 8E). This etching of the sacrificial material of the portion 1002 can be carried out by oxidizing plasma at a temperature of between approximately 200° C. and 300° C. When the material of the portion 1002 is of a similar nature to that of the organic layer 104, this step of etching, such as dry etching, the portion of sacrificial material 1002 can at the same time carry out an etching of the part of the organic layer 104 situated under the microelectronic device 1000 and which corresponds to the region intended to be encapsulated in the cavity, thus releasing the various parts of the device 1000, these various parts corresponding for example to movable parts when the device 1000 is of the MEMS/NEMS type. In a variant, the etching of the portion 1002 and of the part of the organic layer 104 can be obtained by implementing two distinct etching steps, the etching of the part of the organic layer 104 being a dry etching.

Because the organic material of the layer 104 is able to be etched selectively with respect to the semiconductor of the top layer 106, the dry etching carried out in order to remove part of the sacrificial layer 104 does not degrade the material of the top layer 106.

In this way a cavity 1008 is obtained in which the microelectronic device 1000 is encapsulated, the encapsulation layer or layers 1004 forming the cap of this cavity 1008.

The opening or openings 1006 previously produced through the encapsulation layer or layers 1004 are then plugged hermetically, by depositing for example a hermetic layer 1010 of semiconductor oxide or nitride, or metal. The thickness of the hermetic layer 1010 may be between 1 and a few microns (for example less than or equal to 10 μm) according to the size of the openings 1006 to be plugged.

This hermetic closure of the cavity 1008 can be carried out in a controlled atmosphere (pressure, gas, etc.) corresponding to the required atmosphere in the cavity 1008.

FIG. 9 shows a microelectronic device 1000 encapsulated not by PCM but by transferring a cap 1020. This cap 1020, for example comprising, or composed of, semiconductor such as silicon, or glass, can be secured to the top layer 106 by means of a sealing bead 1022, obtained for example by anodic sealing or metallic sealing, or by direct sealing between the cap 1020 and the top layer 106.

The cap 1020 comprises an etched part forming at least part of the cavity 1024 in which the device 1000 is encapsulated. When the cap 1020 is transferred to the top layer 106, the organic layer 104 may not yet be etched.

In order to release the device 1000, an opening 1026 (or several openings) is then produced through the cap 1020, thus forming an access to the device 1000. Next the part of the organic layer 104 situated under the device 1000 is eliminated, via the implementation of steps similar to those previously described, in order to release the device 1000 (dry etching). The opening 1026 is then plugged hermetically via the deposition of a plugging material on the cap 1020, located or not at the opening 1026.

In a variant, it is possible first of all to produce the device 1000 and then encapsulate it via the transfer of the cap 1020.

In FIGS. 8A to 8F and 9, a single microelectronic device 1000 is encapsulated in the cavity 1008 or 1024. It is however possible to encapsulate several microelectronic devices in the same atmosphere, for example by encapsulating several microelectronic devices in the same cavity or by effecting a collective encapsulation of several microelectronic devices in different cavities.

In all the embodiments previously described, the microelectronic substrate may comprise one or more portions of dielectric material the hardness of which is greater than that of the organic material, disposed in the layer of organic material, and the thickness of which is substantially equal to that of the layer of organic material.

1. A microelectronic substrate comprising at least:
a support layer,
a top layer comprising at least one semiconductor,
a layer comprising at least one organic material able to be etched selectively with respect to the semiconductor of the top layer by using a dry etching, and disposed between the support layer and the top layer,
and also comprising one or more portions of dielectric material the hardness of which is greater than that of the organic material, disposed in the layer of organic material, and the thickness of which is substantially equal to that of the layer of organic material.

2. The microelectronic substrate according to claim 1, in which the organic material is a photosensitive resin.

3. The microelectronic substrate according to claim 1, also comprising at least one layer of getter material disposed between the support layer and the layer of organic material.

4. The microelectronic substrate according to claim 1, also comprising at least two other layers fixed directly against each other and disposed between the layer of organic material and the top layer.

5. The microelectronic substrate according to claim 1, in which at least one of the portions of dielectric material disposed in the layer of organic material forms a closed contour around at least one region of the layer of organic material.

6. A microelectronic device comprising a microelectronic substrate according to claim 1, comprising at least one portion of the top layer suspended above the support layer.

7. A method of producing a microelectronic substrate, comprising at least the steps of:
producing a layer comprising at least one organic material on a support layer;
producing a top layer comprising at least one semiconductor on the layer of organic material, the organic material being able to be etched selectively with respect to the semiconductor of the top layer using a dry etching;
and also comprising, before the production of the layer of organic material, a step of producing one or more portions of a dielectric material the hardness of which is greater than that of the organic material, on the support layer, the thickness of which is substantially equal to that of the layer of organic material, the layer of organic material then being produced on the support layer, around said portion or portions.

8. The method according to claim 7, also comprising, before the production of the layer of organic material, a step of producing at least one layer of getter material on the support layer, the layer of organic material and the portion or portions of dielectric material being produced on the layer of getter material.

9. The method according to claim 7, in which the production of the top layer on the layer of organic material comprises at least one step of direct bonding between two other layers, one being disposed against the top layer and the other being disposed against the layer of organic material.

10. The method according to claim 7, also comprising, before the production of the top layer, a step of producing one or more holes through the layer of organic material.

11. The method according to claim 7, also comprising the production of at least one of the portions of dielectric material such that said portion forms a closed contour around at least one region of the layer of organic material.

12. A method of producing at least one microelectronic device, comprising at least the steps of:
producing the microelectronic device in the top layer of a microelectronic substrate according to claim 1;
elimination by dry etching of part of the layer of organic material disposed under the microelectronic device so that the microelectronic device comprises at least one portion of the top layer suspended above the support layer.

13. The method according to claim 12, comprising in addition, between the step of producing the microelectronic device and the step of eliminating part of the layer of organic, at least the steps of:
producing, on the top layer of the microelectronic substrate, a portion of material able to be etched selectively with respect to the semiconductor material of the top layer and covering the microelectronic device;
depositing at least one encapsulation layer on the portion of material covering the microelectronic device;
etching the portion of material covering the microelectronic device through at least one opening produced through the encapsulation layer;
and also comprising, after the step of elimination of part of the layer of organic material disposed under the microelectronic device, a step of hermetic closure of the opening or openings produced through the encapsulation layer.

14. The method according to claim 13, in which the step of etching the portion of material covering the microelectronic device and the step of eliminating part of the layer of organic material are a single dry etching step.

15. The method according to claim 12, also comprising, between the step of producing the microelectronic device and the step of eliminating part of the layer of organic material, a step of transfer and sealing of a cap on the top layer, in which the elimination of part of the layer of organic material is carried out through at least one opening formed through the cap, and also comprising a step of hermetic closure of the opening carried out through the cap.
